(19) United States
(12) Patent Application Publication
(10) Pub. No.: US 2026/0333811 A1
(43) Pub. Date: Oct. 22, 2026

(54) SEMICONDUCTOR STRUCTURE AND MANUFACTURING METHOD THEREOF

(71) Applicant: ENKRIS SEMICONDUCTOR, INC., Suzhou (CN)

(72) Inventor: Kai CHENG, Suzhou (CN)

(73) Assignee: ENKRIS SEMICONDUCTOR, INC., Suzhou (CN)

(21) Appl. No.: 19/727,268

(22) Filed: Jul. 1, 2026

Related U.S. Application Data
(63) Continuation of application No. 18/323,343, filed on May 24, 2023, now abandoned.

(30) Foreign Application Priority Data
Nov. 29, 2022 (CN) 202211513761.8

(51) Int. Cl. H10D 62/85; H10D 30/01; H10D 30/47; H10D 62/10

(52) U.S. Cl. CPC H10D 62/8503; H10D 30/015; H10D 30/475; H10D 62/102

(57) ABSTRACT

A semiconductor structure includes: a substrate, a channel layer, a barrier layer and a P-type semiconductor layer sequentially stacked in a first direction. The P-type semiconductor layer includes a high-resistance passivation region and an activation region, and the high-resistance passivation region is located on a side, away from the substrate, of the activation region. When a semiconductor device is in an off state, the activation region of the P-type semiconductor layer may deplete 2DEG at the channel to realize an enhancement-mode device. The high-resistance passivation region is passivated to form a high-resistance structure, which may reduce a gate leakage current in the off state and improve power characteristics of the semiconductor device.

### CROSS-REFERENCE TO RELATED APPLICATIONS

The present application is a continuation application of U.S. Patent Application No. 18/323,343, filed on May 24, 2023, which claims priority to Chinese Patent Application No. 202211513761.8, filed on Nov. 29, 2022. The disclosures of the aforementioned applications are hereby incorporated by reference in their entireties.

### TECHNICAL FIELD

The present application relates to the field of semiconductor technologies, in particular, to a semiconductor structure and a manufacturing method thereof.

### BACKGROUND

Compared with the first and the second generation semiconductor materials, the third generation semiconductor materials, especially gallium nitride (GaN)-based materials, have a lot of advantages, such as, large bandgap width, high breakdown field strength, high electron mobility, and strong radiation resistance. GaN-based High Electron Mobility Transistor (HEMT) devices have great development potential in high-frequency and high-power fields such as wireless communication base stations, radar, and automotive electronics.

Usually, GaN-based HEMT devices are depletion-type field effect transistors. if a negative starting voltage is used in radio frequency microwave applications, a circuit structure may become complicated, and an anti-misstart protection function of a circuit may also be affected, which reduces the safety of the circuit. Therefore, it is necessary to carry out research on enhancement-mode GaN-based HEMT devices.

Common methods for realizing enhancement-mode devices include trench gate technology, fluorine ion implantation technology and P-type gate technology. P-type gate technology is to add a P-type GaN-based epitaxial layer between a gate metal and a barrier layer to reduce a barrier height of the barrier layer. Due to a conduction band difference between the P-type GaN-based epitaxial layer and the barrier layer, a conduction band of an entire heterojunction is raised above the Fermi level, and a two-Dimensional Electron Gas (2DEG) at a channel below a gate is depleted to realize enhancement-mode. However, during a manufacturing process of a device, the P-type GaN-based epitaxial layer, between a gate and a source, and between a gate and a drain, needs to be etched away, which makes it difficult to control etching accuracy and introduces etching damage, eventually leading to a decrease in output current density, an increase in leakage current of the gate, and a decrease in device stability.

### SUMMARY

In view of this, embodiments of the present application provide a semiconductor structure to solve the technical problem of gate leakage current of power devices in existing technologies.

According to one aspect of the present application, a semiconductor structure provided by an embodiment of the present application includes: a substrate, a channel layer, a barrier layer and a P-type semiconductor layer sequentially stacked in a first direction. The P-type semiconductor layer includes a high-resistance passivation region and an activation region, and the high-resistance passivation region is located on a side, away from the substrate, of the activation region.

In one embodiment, a hydrogen concentration of the high-resistance passivation region is higher than a hydrogen concentration of the activation region.

In one embodiment, the hydrogen concentration of the high-resistance passivation region is less than or equal to a magnesium concentration of the activation region.

In one embodiment, the hydrogen concentration of the high-resistance passivation region is 1E18/cm3 to 1E20/cm3.

In one embodiment, the hydrogen concentration of the high-resistance passivation region presents an increasing trend in the first direction.

In one embodiment, the increasing trend is any one or a combination of a linear increasing, a stepped increasing and a curved increasing.

In one embodiment, the hydrogen concentration of the high-resistance passivation region presents a trend of increasing first and then decreasing in the first direction.

In one embodiment, the hydrogen concentration of the high-resistance passivation region presents a trend of decreasing first and then increasing in a direction parallel to the substrate.

In one embodiment, an oxygen concentration of the high-resistance passivation region presents a trend of increasing first and then decreasing in a direction parallel to the substrate.

In one embodiment, a thickness of the P-type semiconductor layer in the first direction is 20 to 150 nm.

In one embodiment, a thickness of the high-resistance passivation region in the first direction is 1 to 50 nm.

In one embodiment, a projected area of the high-resistance passivation region on the substrate is equal to a projected area of the activation region on the substrate.

In one embodiment, a thickness, in the first direction, of the high-resistance passivation region decreases first and then increases along a direction parallel to the substrate.

In one embodiment, the semiconductor structure further includes: a gate, located on a side, away from the substrate, of the P-type semiconductor layer, and a source and a drain, located on a side, away from the substrate, of the channel layer. The source and the drain are located on both sides of the gate.

According to another aspect of the present application, a manufacturing method of a semiconductor structure provided by an embodiment of the present application includes: epitaxially preparing a channel layer, a barrier layer and a P-type semiconductor material layer on a side of a substrate along a first direction in sequence; activating the P-type semiconductor material layer to transform into a P-type semiconductor layer; and performing passivation treatment on a side, away from the substrate, of the P-type semiconductor layer to form a high-resistance passivation region, where the P-type semiconductor layer without the passivation treatment is an activation region, and the high-resistance passivation region is located on a side, away from the substrate, of the activation region.

In one embodiment, the passivation treatment is hydrogen ion treatment or N-type impurity compensation.

In one embodiment, the passivation treatment includes: depositing a SiN layer on the side, away from the substrate, of the P-type semiconductor layer, where a hydrogen in the SiN layer diffuses backward to the side, away from the substrate, of the P-type semiconductor layer to form the high-resistance passivation region.

In one embodiment, the performing passivation treatment on a side, away from the substrate, of the P-type semiconductor layer to form a high-resistance passivation region includes: preparing a protective dielectric layer on the side, away from the substrate, of the P-type semiconductor layer; and performing the passivation treatment on the protective dielectric layer and the side, away from the substrate, of the P-type semiconductor layer.

In one embodiment, the activating the P-type semiconductor material layer to transform into a P-type semiconductor layer and the performing passivation treatment on a side, away from the substrate, of the P-type semiconductor layer to form a high-resistance passivation region are performed simultaneously: a mode of activating the P-type semiconductor material layer is oxygen ion implantation, and the P-type semiconductor material layer is transformed into the P-type semiconductor layer; and the passivation treatment is hydrogen ion implantation, and an implantation depth is at the side, away from the substrate, of the P-type semiconductor layer.

### BRIEF DESCRIPTION OF THE DRAWINGS

FIG. 1 is a schematic structural diagram of a semiconductor structure according to an embodiment of the present application.

FIG. 2 is a flowchart of a manufacturing method of a semiconductor structure according to an embodiment of the present application.

FIGS. 3 to 5 are schematic diagrams of intermediate structures of a manufacturing method according to an embodiment of the present application.

FIG. 6 is a flowchart of a method of step S13 according to an embodiment of the present application.

FIGS. 7 to 8 are schematic diagrams of intermediate structures of a manufacturing method according to an embodiment of the present application.

FIG. 9 is a flowchart of a manufacturing method of a semiconductor structure according to an embodiment of the present application.

FIG. 10 (a) is a stacked structure diagram of a gate, a high-resistance passivation region and an activation region.

FIG. 10 (b) is a schematic diagram of a hydrogen concentration of a high-resistance passivation region according to an embodiment of the present application.

FIG. 10 (c) is a schematic diagram of a hydrogen concentration of a high-resistance passivation region according to another embodiment of the present application.

FIG. 10 (d) is a schematic diagram of a hydrogen concentration of a high-resistance passivation region according to another embodiment of the present application.

FIG. 10 (e) is a schematic diagram of a hydrogen concentration of a high-resistance passivation region according to another embodiment of the present application.

FIG. 11 is a schematic diagram of a hydrogen concentration of a high-resistance passivation region according to another embodiment of the present application.

FIG. 12 (a) is a schematic diagram of a hydrogen concentration of a high-resistance passivation region according to another embodiment of the present application.

FIG. 12 (b) is a schematic diagram of an oxygen concentration of a high-resistance passivation region according to an embodiment of the present application.

FIG. 13 is a schematic structural diagram of a semiconductor structure according to an embodiment of the present application.

### DETAILED DESCRIPTION OF THE EMBODIMENTS

The following will clearly and completely describe technical solutions in the embodiments of the present application with reference to the accompanying drawings in the embodiments of the present application. Apparently, the described embodiments are only some, not all, embodiments of the present application. Based on the embodiments in the present application, all other embodiments obtained by persons of ordinary skill in the art without making creative efforts belong to the protection scope of the present application.

In order to solve the above problems, the present application provides a semiconductor structure, including a substrate, a channel layer, a barrier layer and a P-type semiconductor layer that are stacked sequentially in a first direction. The P-type semiconductor layer includes a high-resistance passivation region and an activation region, and the high-resistance passivation region is located on a side, away from the substrate, of the activation region.

FIG. 1 is a schematic structural diagram of a semiconductor structure according to an embodiment of the present application. As shown in FIG. 1, the semiconductor structure 100 includes: a substrate 10, a channel layer 20, a barrier layer 30 and a P-type semiconductor layer 40 sequentially stacked in a first direction X. The P-type semiconductor layer 40 includes a high-resistance passivation region 41 and an activation region 42, and the high-resistance passivation region 41 is located on a side, away from substrate10, of the activation region 42.

Specifically, a heterostructure formed by the channel layer 20 and the barrier layer 30 allows a formation of a high concentration of 2DEG at a heterojunction interface, and a conductive channel is generated at the heterojunction interface of the channel layer 20. When the semiconductor device 100 is in an off state, the activation region 42 of the P-type semiconductor layer 40 may deplete the 2DEG in the channel to realize an enhancement-mode device. The high-resistance passivation region 41 is passivated to form a high-resistance structure, which may reduce a gate leakage current in the off-state and improve power characteristics of the semiconductor device.

In one embodiment, as shown in FIG. 1, the semiconductor structure 100 further includes: a gate 53 located on a side, away from the substrate 10, of the P-type semiconductor layer 40, and a source 51 and a drain 52 located on a side, away from the substrate 10, of the channel layer 20. The source 51 and the drain 52 are located on both sides of the gate 53.

It should be noted that FIG. 1 only shows that the source 51 and the drain 52 are located on a side, away from the substrate 10, of the barrier layer 30. Optionally, the barrier layer 30 is thinned at corresponding positions of the source 51 and the drain 52. Optionally, the source 51 and the drain 52 penetrate through the barrier layer 30 and directly contact with the channel layer 20.

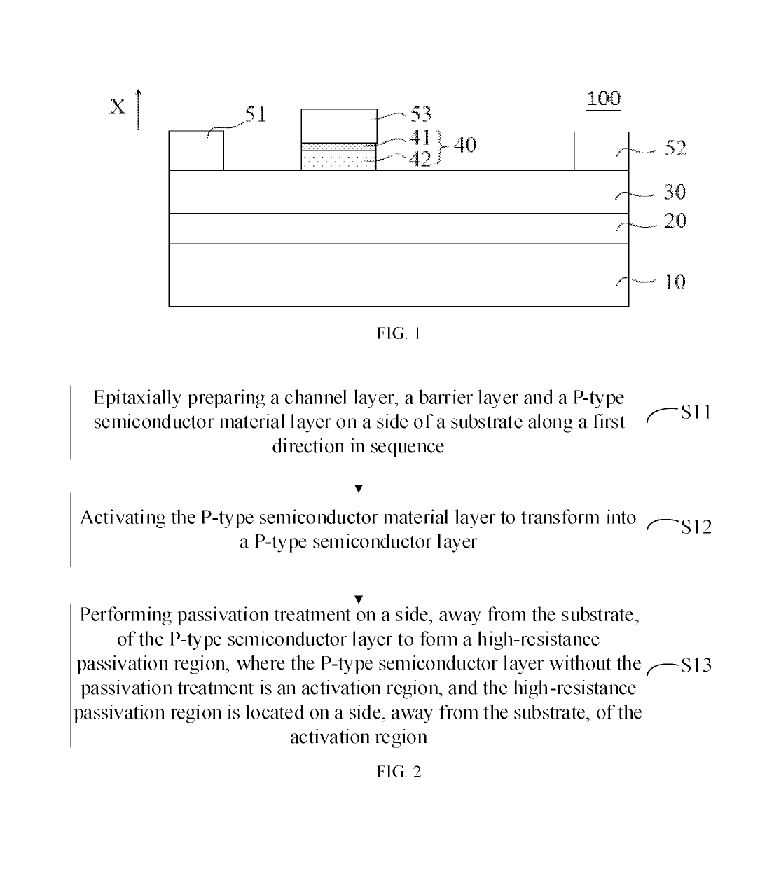

According to another aspect of the present application, FIG. 2 is a flowchart of a manufacturing method of a semiconductor structure according to an embodiment of the present application, and FIGS. 3 to 5 are schematic diagrams of intermediate structures of a manufacturing method according to an embodiment of the present application. As shown in FIG. 2, a manufacturing method of a semiconductor structure provided by an embodiment of the present application includes:

Step S11, as shown in FIG. 3, epitaxially preparing a channel layer 20, a barrier layer 30 and a P-type semiconductor material layer 401 on a side of a substrate 10 along a first direction X in sequence;

Step S12, as shown in FIG. 4, activating the P-type semiconductor material layer 401 to transform into a P-type semiconductor layer 40; and

Step S13, as shown in FIG. 5, performing passivation treatment on a side, away from the substrate 10, of the P-type semiconductor layer 40 to form a high-resistance passivation region 41, where the P-type semiconductor layer 40 without the passivation treatment is an activation region 42, and the high-resistance passivation region 41 is located on a side, away from the substrate 10, of the activation region 42.

Specifically, in step S11, an epitaxial preparation method includes: Atomic Layer Deposition (ALD), or Chemical Vapor Deposition (CVD), or Molecular Beam Epitaxy (MBE), or Plasma Enhanced Chemical Vapor Deposition (PECVD), or Low Pressure Chemical Vapor Deposition (LPCVD), or Metal-Organic Chemical Vapor Deposition (MOCVD), or a combination thereof.

Specifically, in step S12, a P-type ion of the P-type semiconductor material layer 401 may include any one of Mg, Zn, Ca, Sr, Ba or C, and a method for activating the P-type semiconductor material layer 401 includes: high temperature annealing activation, and oxygen doping treatment. For example, the P-type ion of the P-type semiconductor material layer 401 is Mg, and in an activation process, the Mg-H bond is broken, Mg is released, electrical activity of Mg is improved, electron scattering is reduced, and a gate voltage during use process is increased.

Specifically, in step S13, passivation treatment is performed on the side, away from the substrate 10, of the P-type semiconductor layer 40, and the passivation treatment is hydrogen ion treatment or N-type impurity compensation. Specifically, taking the P-type ion of the P-type semiconductor material layer 401 as Mg as an example, the hydrogen ion treatment can recombine with Mg to form a Mg-H bond, and the donor Mg is passivated to form a high-resistance structure; or, N-type impurity compensation can neutralize a hole concentration of P-type semiconductor layer 40 to form a high-resistance structure. The high-resistance passivation region 41 is located on the side, away from the substrate 10, of the activation region 42, thereby reducing the gate leakage when the semiconductor device is off. Optionally, the hydrogen ion treatment includes any one of hydrogen plasma treatment, hydrogen ion implantation or hydrogen gas introduction.

Optionally, after the high-resistance passivation region 41 is prepared, a gate 53, a source 51 and a drain 52 are prepared by sputtering process to prepare the semiconductor structure 100 shown in FIG. 1.

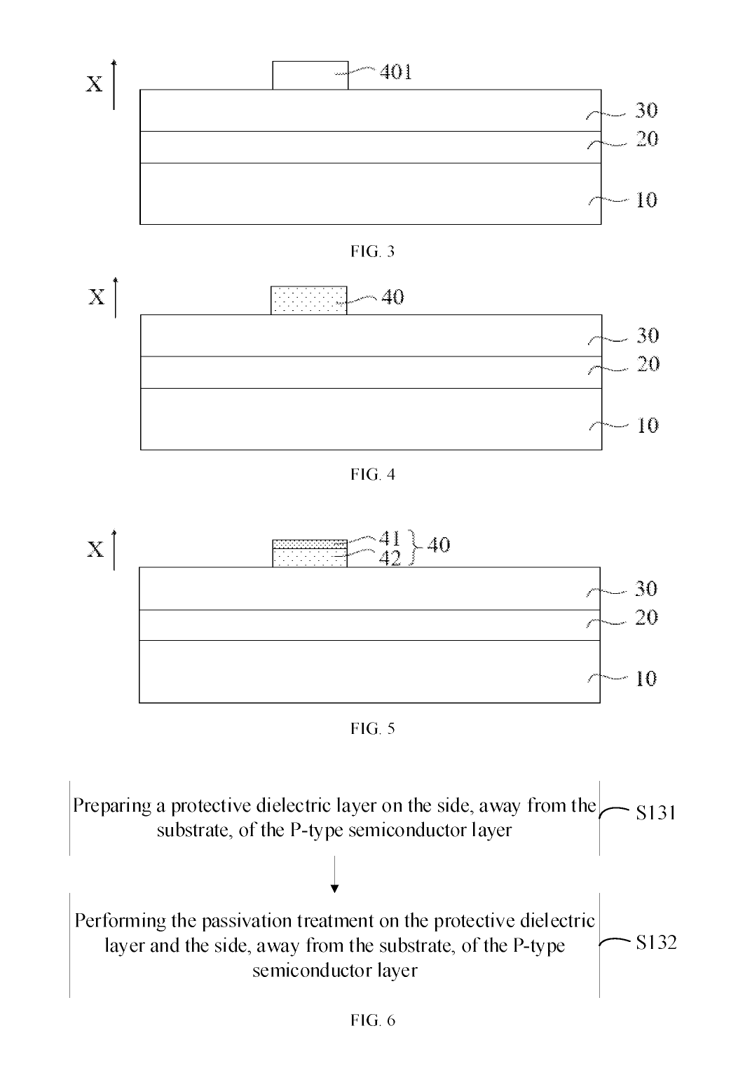

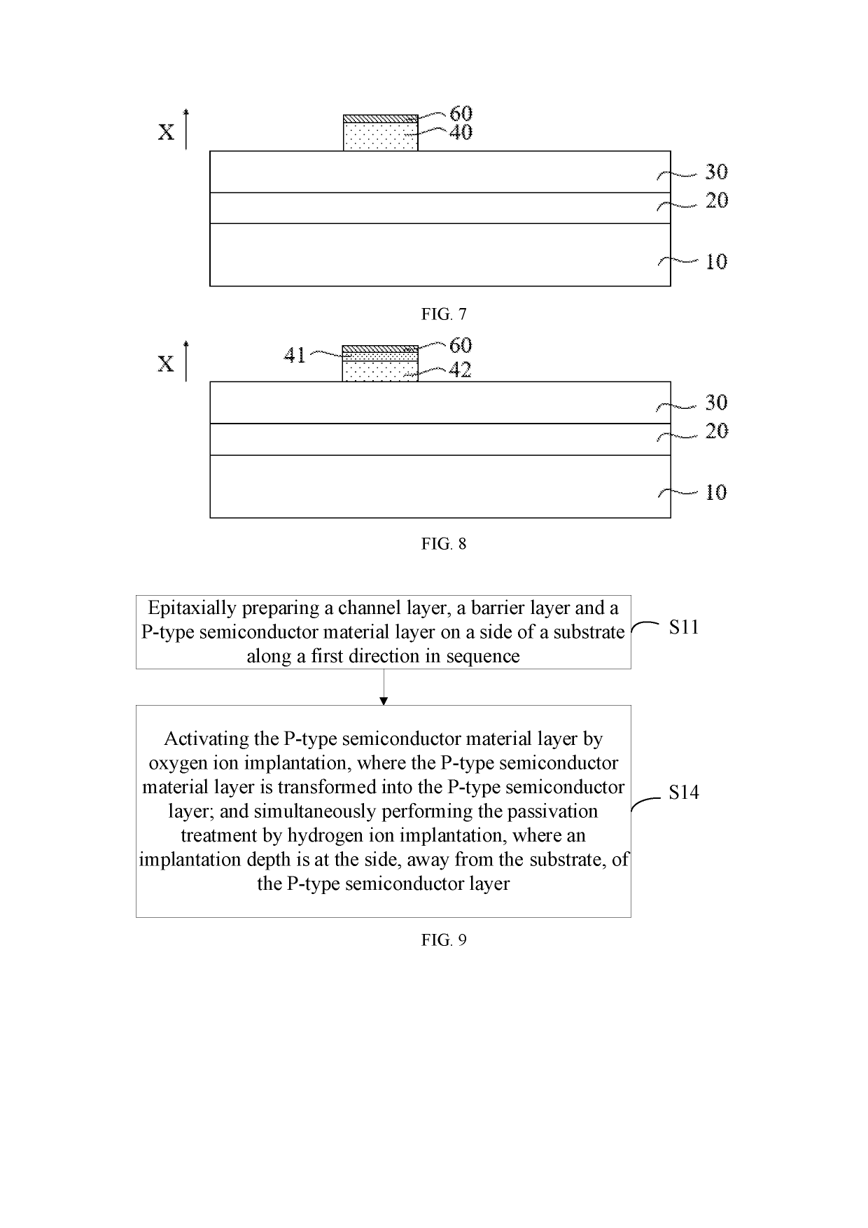

In one embodiment, FIG. 6 is a flowchart of a method of step S13 according to an embodiment of the present application, and FIGS. 7 to 8 are schematic diagrams of intermediate structures of a manufacturing method according to an embodiment of the present application. As shown in FIG. 6, step S13 includes:

Step S131, as shown in FIG. 7, preparing a protective dielectric layer 60 on the side, away from the substrate 10, of the P-type semiconductor layer 40; and

Step S132, as shown in FIG. 8, performing the passivation treatment on the protective dielectric layer 60 and the side, away from the substrate 10, of the P-type semiconductor layer 40.

Specifically, in step S131, the protective dielectric layer 60 can control a depth of the passivation treatment on a surface, away from the substrate 10, of the P-type semiconductor layer 40, so as to obtain a high-resistance passivation region 41 with a thinner thickness.

Optionally, after the passivation treatment, the protective dielectric layer 60 is removed by etching. Optionally, the protective dielectric layer 60 is photoresist or SiO2. In one embodiment, FIG. 9 is a flowchart of a manufacturing method of a semiconductor structure according to an embodiment of the present application. As shown in FIG. 9, step S12 and step S13 are performed simultaneously: activating the P-type semiconductor material layer by oxygen ion implantation, where the P-type semiconductor material layer is transformed into the P-type semiconductor layer; and simultaneously performing the passivation treatment by hydrogen ion implantation, where an implantation depth is at the side, away from the substrate, of the P-type semiconductor layer. The combination of step S12 and step S13 is shown as step S14 in FIG. 9.

Specifically, depths of oxygen ion implantation and hydrogen ion implantation are controlled to be different, for example, the oxygen ion implantation is used to activate the whole P-type semiconductor material layer 401; and low-energy hydrogen is used, so that the depth of hydrogen ion implantation is only in the surface, away from the substrate 10, of the P-type semiconductor layer 40 to obtain a thinner high-resistance passivation region 41.

Optionally, before epitaxially preparing the channel layer 20, a nucleation layer and a buffer layer are epitaxially prepared on a side of substrate 10, and then the channel layer 20 is epitaxially prepared on a side, away from substrate 10, of the buffer layer, which can improve crystal quality of the semiconductor structure.

In one embodiment, as shown in FIG. 7 to FIG. 8, the passivation treatment includes: depositing a SiN layer 60 on the side, away from the substrate 10, of the P-type semiconductor layer 40. A hydrogen in the SiN layer 60 diffuses backward to the side, away from substrate10, of the P-type semiconductor layer 40 to form the high-resistance passivation region 41. Specifically, a direction of hydrogen backward diffusion is from the SiN layer 60 to the P-type semiconductor layer 40. Optionally, the SiN layer has a hydrogen content of 5% to 20%, and the hydrogen can diffuse to the side, away from the substrate 10, of the P-type semiconductor layer 40 during an annealing process to form the high-resistance passivation region 41.

In one embodiment, a hydrogen concentration of the high-resistance passivation region 41 is higher than a hydrogen concentration of the activation region 42.

Specifically, through hydrogen ion treatment, H and Mg are combined to form Mg-H bonds, and the donor Mg is passivated to form the high-resistance passivation region 41, that is, to form a high-resistance structure. Specifically, the hydrogen concentration may refer to the number of hydrogen atoms per unit volume.

In one embodiment, the hydrogen concentration of the high-resistance passivation region 41 is less than or equal to a magnesium concentration of the activation region 42.

Specifically, the P-type ion of the P-type semiconductor layer 40 is magnesium, and the hydrogen concentration used in the hydrogen ion treatment process is less than or equal to the magnesium concentration of the activation region 42, so as to ensure that the donor Mg on a surface, away from the substrate 10, of the P-type semiconductor layer 40 is passivated to form the high-resistance passivation region 41, that is, to form a high-resistance structure.

In one embodiment, the hydrogen concentration of the high-resistance passivation region 41 is 1E18/cm3 to 1E20/cm3.

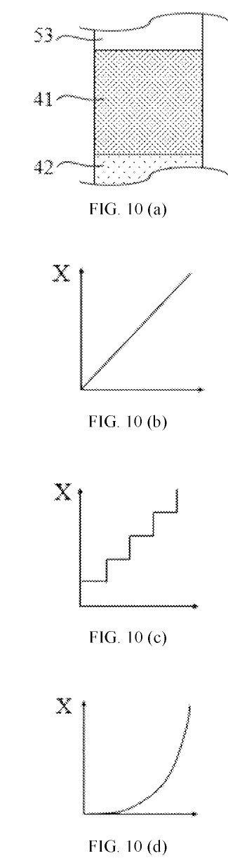

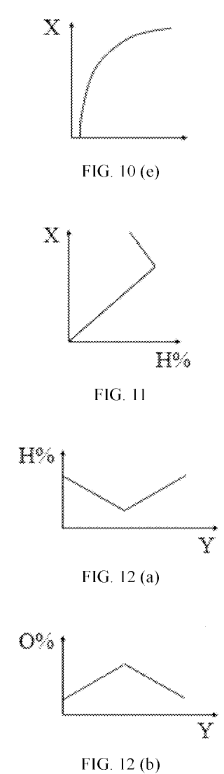

In one embodiment, FIG. 10 (a) shows a stacked structure diagram of a gate 53, a high-resistance passivation region 41 and an activation region 42, in which only part of the gate 53 and the activation region 42 are shown. As shown in FIG. 10 (b) to FIG. 10 (e), the hydrogen concentration of the high-resistance passivation region 41 presents an increasing trend in the first directionX. Specifically, the increasing trend appears as any one or a combination of a linear increasing as shown in FIG. 10 (b), a stepped increasing as shown in FIG. 10 (c), and a curved increasing as shown in FIG. 10 (d) and FIG. 10 (e).

Specifically, as shown in FIG. 10 (b) to FIG. 10 (e), the hydrogen concentration of the high-resistance passivation region 41 presents an increasing trend in the first direction X, in other words, a position of the hydrogen ion treatment is on the surface, away from the substrate 10, of the P-type semiconductor layer 40, and the hydrogen concentration of the high-resistance passivation region 41 reaches the maximum on an upper surface of the P-type semiconductor layer 40 or on a surface, close to the gate 53, of the P-type semiconductor layer 40, which can better improve the gate leakage current.

It should be noted that the horizontal coordinate of the schematic diagram of hydrogen concentration shown in FIG. 10 (b) to FIG. 10 (e) is hydrogen concentration H %, and the vertical coordinate is the thickness change in the first direction X. The linear increasing is as shown in FIG. 10 (b), and there is no limit to the slope of the linear increasing of hydrogen concentration in the present application. The stepped increasing is as shown in FIG. 10 (c), and there is no limit to the step change range of the stepped increasing of hydrogen concentration in the present application. The curved increasing is as shown in FIG. 10 (d) and FIG. 10 (e), and there is no limit to the slope change of the curved increasing of hydrogen concentration in the present application. Optionally, the hydrogen concentration of the high-resistance passivation region 41 presents a combination of the above increasing trends in the first direction X, for example, in the first direction X, the hydrogen concentration first linearly increases and then curvedly increases.

In one embodiment, based on FIG. 10 (a), as shown in FIG. 11, the hydrogen concentration of the high-resistance passivation region 41 presents a trend of increasing first and then decreasing in the first direction X. It should be noted that in the hydrogen ion treatment process, the implantation depth of hydrogen ions can be below the upper surface of the P-type semiconductor layer 40, corresponding to a position with the highest hydrogen concentration. Optionally, in this embodiment, the variation trend of hydrogen concentration may be any one or a combination of linear, curved, and stepped.

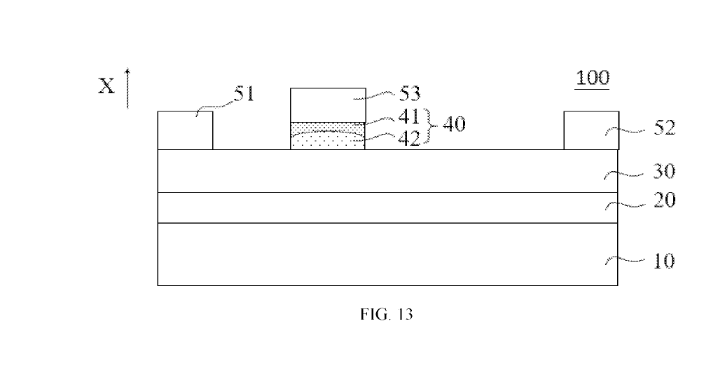

In one embodiment, based on FIG. 10 (a), as shown in FIG. 12 (a), the hydrogen concentration of the high-resistance passivation region 41 presents a trend of decreasing first and then increasing in a direction Y parallel to the substrate 10. It can be understood that the high-resistance passivation region 41 has a higher hydrogen concentration in a side region along the direction Y parallel to the substrate 10. The gate leakage current is prone to occur on a side of the gate 53 or a side of the P-type semiconductor layer 40, so the higher the hydrogen concentration in a side position of the high-resistance passivation region 41, the better the gate leakage current phenomenon can be improved. Specifically, the direction Y is perpendicular to the first direction X.

In one embodiment, as shown in FIG. 12 (b), an oxygen concentration of the high-resistance passivation region 41 presents a trend of increasing first and then decreasing in a direction parallel to the substrate 10. Specifically, activation treatment of the P-type semiconductor layer 40 may be an oxygen injection process. It can be understood that the oxygen concentration of the side region of the high-resistance passivation region 41 is relatively low in the direction Y parallel to the substrate 10. The gate leakage current is prone to occur on the side of the gate 53 or the side of the P-type semiconductor layer 40, so the lower the oxygen concentration in the side position of the high-resistance passivation region 41, that is, the lower the activation efficiency at the side position of the P-type semiconductor layer 40, that is, the stronger the high-resistance passivation effect at the side position, the better the gate leakage current phenomenon can be improved.

It should be noted that, as shown in FIG. 10 (b) to FIG. 10 (e), FIG. 11 and FIG. 12 (a), the starting point of the horizontal and vertical coordinates in the schematic diagrams of hydrogen concentration may not start from zero.

In one embodiment, a thickness of the P-type semiconductor layer 40 in the first directionX is 20 to 150 nm.

In one embodiment, a thickness of the high-resistance passivation region 41 in the first direction X is 1 to 50 nm. Compared with the P-type semiconductor layer 40, the high-resistance passivation region 41 is thinner and is a high-resistance structure, which may reduce the gate leakage current in the off state and improve the power characteristics of the semiconductor device.

In one embodiment, a projected area of the high-resistance passivation region 41 on substrate 10 is equal to a projected area of the activation region 42 on the substrate10. Specifically, the high-resistance passivation region 41 completely covers the activation region 42, and the high-resistance passivation region 41 is a high-resistance structure, which may reduce gate leakage current in an off state and improve power characteristics of semiconductor devices. In one embodiment, FIG. 13 is a schematic structural diagram of a semiconductor structure according to an embodiment of the present application. As shown in FIG. 13, a thickness, in the first directionX, of the high-resistance passivation region 41 decreases first and then increases along a direction parallel to the substrate 10. It should be noted that the gate leakage current is prone to occur on the side of the gate 53 or the side of the P-type semiconductor layer 40, so the thicker the side position of the high-resistance passivation region 41, the better the gate leakage current phenomenon can be improved. As shown in FIG. 13, a surface of the high-resistance passivation region 41 close to the substrate 10 is arc-shaped; optionally, the surface of the high-resistance passivation region 41 close to the substrate 10 is stepped (not shown).

The present application provides a semiconductor structure and a manufacturing method thereof. The semiconductor structure includes: a substrate, a channel layer, a barrier layer and a P-type semiconductor layer sequentially stacked in a first direction. The P-type semiconductor layer includes a high-resistance passivation region and an activation region, and the high-resistance passivation region is located on a side, away from the substrate, of the activation region. When a semiconductor device is in an off state, the activation region of the P-type semiconductor layer may deplete 2DEG at the channel to realize an enhancement-mode device. The high-resistance passivation region is passivated to form a high-resistance structure, which may reduce a gate leakage current in the off state and improve power characteristics of the semiconductor device.

It should be understood that the term of “including” and its variants used in the present application are open including, that is “including but not limited to”. The term of “one embodiment” means “at least one embodiment”; and the term of “another embodiment” means “at least one further embodiment”. In this specification, the schematic representations of the above terms are not necessarily directed to the same embodiment or example. Furthermore, the described specific features, structures, materials or characteristics may be combined in any suitable manner in any one or more embodiments or examples. In addition, those skilled in the art can combine and associate different embodiments or examples and features of different embodiments or examples described in this specification without conflicting with each other.

The above are only preferred embodiments of the present application, and are not intended to limit the present application. Any modifications, equivalent replacements made within the spirit and principles of the present application shall be included in the protection scope of the present application.

What is claimed is:

1. A semiconductor structure, comprising:
a substrate, a channel layer, a barrier layer, and a P-type semiconductor layer sequentially stacked in a first direction;
wherein the P-type semiconductor layer comprises a high-resistance passivation region and an activation region, the high-resistance passivation region is located on a side, away from the substrate, of the activation region, and a thickness, in the first direction, of the high-resistance passivation region decreases first and then increases along a direction parallel to the substrate.

2. The semiconductor structure according to claim 1, wherein a hydrogen concentration of the high-resistance passivation region is higher than a hydrogen concentration of the activation region.

3. The semiconductor structure according to claim 2, wherein the hydrogen concentration of the high-resistance passivation region is less than or equal to a magnesium concentration of the activation region.

4. The semiconductor structure according to claim 2, wherein the hydrogen concentration of the high-resistance passivation region is 1E18/cm3 to 1E20/cm3.

5. The semiconductor structure according to claim 2, wherein the hydrogen concentration of the high-resistance passivation region presents an increasing trend in the first direction.

6. The semiconductor structure according to claim 5, wherein the increasing trend is any one or a combination of a linear increasing, a stepped increasing, and a curved increasing.

7. The semiconductor structure according to claim 2, wherein the hydrogen concentration of the high-resistance passivation region presents a trend of increasing first and then decreasing in the first direction.

8. The semiconductor structure according to claim 2, wherein the hydrogen concentration of the high-resistance passivation region presents a trend of decreasing first and then increasing in the direction parallel to the substrate.

9. The semiconductor structure according to claim 2, wherein an oxygen concentration of the high-resistance passivation region presents a trend of increasing first and then decreasing in the direction parallel to the substrate.

10. The semiconductor structure according to claim 1, wherein a thickness of the P-type semiconductor layer in the first direction is 20 to 150 nm.

11. The semiconductor structure according to claim 10, wherein a thickness of the high-resistance passivation region in the first direction is 1 to 50 nm.

12. The semiconductor structure according to claim 1, wherein a projected area of the high-resistance passivation region on the substrate is equal to a projected area of the activation region on the substrate.

13. The semiconductor structure according to claim 1, wherein a surface of the high-resistance passivation region close to the substrate is arc-shaped or stepped.

14. The semiconductor structure according to claim 1, wherein a thickness, in the first direction, of the activation region increases first and then decreases along the direction parallel to the substrate.

15. The semiconductor structure according to claim 1, further comprising:
a gate, located on a side, away from the substrate, of the P-type semiconductor layer, and
a source and a drain, located on a side, away from the substrate, of the channel layer,
wherein the source and the drain are located on both sides of the gate.

16. A manufacturing method of a semiconductor structure, comprising:
epitaxially preparing a channel layer, a barrier layer, and a P-type semiconductor material layer on a side of a substrate along a first direction in sequence;
activating the P-type semiconductor material layer to transform into a P-type semiconductor layer; and
performing passivation treatment on a side, away from the substrate, of the P-type semiconductor layer to form a high-resistance passivation region, wherein the P-type semiconductor layer without the passivation treatment is an activation region, the high-resistance passivation region is located on a side, away from the substrate, of the activation region, and a thickness, in the first direction, of the high-resistance passivation region decreases first and then increases along a direction parallel to the substrate.

17. The manufacturing method according to claim 16, wherein the passivation treatment is hydrogen ion treatment or N-type impurity compensation.

18. The manufacturing method according to claim 16, wherein the passivation treatment comprises: depositing a SiN layer on the side, away from the substrate, of the P-type semiconductor layer, wherein a hydrogen in the SiN layer diffuses backward to the side, away from the substrate, of the P-type semiconductor layer to form the high-resistance passivation region.

19. The manufacturing method according to claim 16, wherein the performing passivation treatment on a side, away from the substrate, of the P-type semiconductor layer to form a high-resistance passivation region comprises:
preparing a protective dielectric layer on the side, away from the substrate, of the P-type semiconductor layer; and
performing the passivation treatment on the protective dielectric layer and the side, away from the substrate, of the P-type semiconductor layer.

20. The manufacturing method according to claim 16, wherein the activating the P-type semiconductor material layer to transform into a P-type semiconductor layer and the performing passivation treatment on a side, away from the substrate, of the P-type semiconductor layer to form a high-resistance passivation region are performed simultaneously:
a mode of activating the P-type semiconductor material layer is oxygen ion implantation, and the P-type semiconductor material layer is transformed into the P-type semiconductor layer; and
the passivation treatment is hydrogen ion implantation, and an implantation depth is at the side, away from the substrate, of the P-type semiconductor layer.
